(19) United States
(12) Patent Application Publication
(10) Pub. No.: US 2010/0170953 A1
(43) Pub. Date: Jul. 8, 2010

(54) ELECTRONIC MODULE AND PROCEDURE FOR AT LEAST THE PARTIAL SCRAPPING OF THE ELECTRONIC MODULE

(76) Inventor: Stephan Schaade, Buchloe (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 12/294,658

(22) PCT Filed: Apr. 3, 2006
(86) PCT No.: PCT/EP2006/003022

§ 371 Date: Sep. 26, 2008

(51) Int. Cl. G06K 19/077; H05K 7/00; B23P 19/00

(52) U.S. Cl. 235/492; 361/728; 361/736; 29/426.1

(57) ABSTRACT

The electronic module (BG) incorporates a specified separation edge (SAK, SAK1, SAK2, SAK3) for the mechanical, irreversible separation of a separable part (AT, AT1, AT2, AT3) of the module (BG) from the remainder of the module (BGR), both the separable part (AT, AT1, AT2, AT3) and the module remainder (BGR) incorporating essentially interacting circuit components (ST1, ST2) for an intended electrotechnical operation of the module (BG). By separating the separable part (AT, AT1, AT2, AT3) the electrotechnical operation of the module (BG) can be permanently deactivated.

### CROSS-REFERENCE TO RELATED APPLICATIONS

This application is a U.S. national stage application of International Application No. PCT/EP2006/003022 filed Apr. 3, 2006, the contents of which are hereby incorporated by reference in their entirety.

### TECHNICAL FIELD

This application relates to an electronic module and procedure for at least the partial scrapping of the electronic module.

### BACKGROUND

Known communication and/or data processing systems are frequently installed in so-called shelf units in which the electronic modules needed for the system are inserted in a rack. For data connection between the modules and to supply the modules with power a so-called backplane with interconnected bus slots for the modules is frequently integrated in the rack, via which the modules communicate with each other.

Systems of this type can be flexibly set up and configured as wide-ranging scope for various combinations of modules is provided. For example, depending on what is required, in a private branch exchange telephone system set up in this way at one customer, in addition to several modules for a connection of internal telephones, several modules for a connection to a public telephone network can also be provided, whereas at a different customer a connection to a public telephone network is created by means of a voice-over IP gateway module (IP: Internet Protocol) via a data network and, moreover, no or just a few modules are provided for a direct connection to a public telephone network. To match these different requirements private branch exchange telephone systems can be operated with a different combination of modules.

Frequently, modules and software components are replaced within the scope of an upgrade of a system to a new functional status. For example, installation of a voice-over gateway module can render one or several modules superfluous for a direct connection to a public telephone network. Moreover, when software components are replaced it is often a problem that the replacement of software components—for example of a central control unit—can require the replacement of existing modules with new modules as the software is not compatible with the existing modules.

To prevent faulty functioning caused by the incompatibility of modules, the manufacturer or the distribution organization may require a confirmation for the removal of an existing module from the customer or from a technician carrying out the removal. This happens for example by sending in or handing in the removed module or by providing confirmation that it has been scrapped, for example by a scrapping service. Both of these procedures are, however, work-intensive, expensive and/or manipulatable.

Furthermore, a similar procedure may be necessary if verifiable deactivation or scrapping of an existing module has been agreed under contractual arrangements between a customer and the manufacturer or the distribution organization.

### SUMMARY

It can be made possible to replace, remove and/or at least partially scrap a module in such a way that this can be carried out simply and that evidence of such can be easily provided.

According to an embodiment, an electronic module, may comprise a specified separation edge for the mechanical, irreversible separation of a separable part of the module from a remainder of the module, wherein both the separable part and also the remainder of the module have essentially interacting circuit components for a conventional electrotechnical operation of the module.

According to a further embodiment, through the separation of the separable part, the electrotechnical operation of the module can be permanently deactivated or at least partially restricted. According to a further embodiment, after separation of the separable part, the electrotechnical operation may be performed neither by the separated separable part nor the remainder of the module. According to a further embodiment, along the specified separation edge at least one of a recess, a perforation, and a separable connection can be provided. According to a further embodiment, the specified separation edge may connect a narrow side of the module with a further narrow side of the module continuously along a wide side of the module. According to a further embodiment, the specified separation edge can be on a board. According to a further embodiment, a circuit-board conductor for the electrotechnical operation may cross the specified separation edge and separation of the separable part may cause the crossing conductor to be cut. According to a further embodiment, the conductor can be arranged on at least one of: a surface and inside a board. According to a further embodiment, the module may exhibit a removable or interruptible stabilization mechanism, so that the separable part is fixed by the attached or applied stabilization mechanism. According to a further embodiment, the separable part may exhibit at least one of: an unambiguous and counterfeit-proof identification feature. According to a further embodiment, the identification feature may be stored in and can be read out from a radio tag or a memory on the separable part. According to a further embodiment, the identification feature can be located on at least one of: a sticker on the separable part, is configured as fixedly connected or recessed lettering, and as a hologram on the separable part. According to a further embodiment, from the identification feature at least one of: a module identification number and a serial number for the module can be determined. According to a further embodiment, a radio tag located on the separable part may be inactive in the unseparated condition through the circuit component located on the remainder of the module and on separation of the separable part this circuit component is separated from the radio tag and the radio tag is then activated.

According to another embodiment, a method for the permanent or at least partial deactivation of an electronic module, may comprise the step of mechanically irreversibly separating a separable part of the module along a specified separation edge, wherein both the separable part and the remainder of the module incorporate essentially interacting circuit components for an intended electrotechnical operation of the module.

According to a further embodiment, a radio reader may be linked via a network to an evaluation computer and an identification feature communicated to the radio reader by a radio tag may be communicated further to the evaluation computer. According to a further embodiment, the module, in addition to the conventional electrotechnical operation, may perform a further conventional function and after separation of the separable part the remainder of the module may continue to perform the further intended function. According to a further embodiment, after separation of the separable part the remainder of the module may perform a different, alternative function to the intended electrotechnical operation.

### BRIEF DESCRIPTION OF THE DRAWINGS

Embodiments are explained in more detail below with reference to drawings depicting the following schematics:

FIG. 1 shows a module with a specified separation edge, whereby a separable part is connected with a remainder of the module,

FIG. 2 shows the module with the separable part separated from the remainder of the module,

FIG. 3 shows the module as in FIG. 1 with a protective sleeve to prevent unintended separation of the separable part,

FIG. 4 shows a module with several specified separation edges and several separable parts,

FIG. 5 shows various forms of specified separation edges, and

FIG. 6 shows an arrangement for reading out RFID information from the separable part.

### DETAILED DESCRIPTION

The module according to an embodiment has a specified separation edge for the mechanical, irreversible separation of a separable part of the module from the remainder of the module, whereby both the separable part and the remainder of the module have essentially interacting circuit components for a conventional electrotechnical operation of the module.

According to a further embodiment, the electrotechnical operation of the module can be permanently deactivated by separating the separable part so that the module is rendered incapable of operation or is destroyed, at least partially with regard to functional parts of the module, at a planned or specified time.

The specified separation edge in particular constitutes an edge or a connecting surface between two parts of a module—the separable part and the remainder of the module—along which the two parts can be separated from each other. As a result of mechanical, chemical and/or electrical processing during or after production of the module, the specified separation edge can represent a specified breaking edge, or according to the terminology usually applied, a specified breaking point, at which the module is separated into the separable part and the remainder of the module as a result of mechanical forces applied to the module. The separable part can be broken off from the remainder of the module by the mechanical forces. In addition or alternatively to the mechanical forces the separation of the separable part from the remainder of the module can be supported or initiated by the application of an electrical voltage or a chemical substance.

Separation of the separable part can, in addition, be understood to mean the removal of the separable part from the remainder of the module by mechanical separation of a plug connection which existed before removal between the separable part and the remainder of the module.

According to a further embodiment, the module can consist of a board fitted with passive and/or active components on which the components are connected with each other by means of circuit-board conductors. The specified separation edge on such modules is preferably arranged on the board in such a way that the circuit-board conductors cross through the specified separation edge and the components are arranged on the separable part as well as on the remainder of the module. These components can jointly preferably provide a common function for regular operation of the module which would not be performed after possible removal of components.

Irreversible separation of the separable part in accordance with various embodiments is understood to mean the separation of the separable part from the remainder of the component in such a way that joining the separable part back together again with the remainder of the module would only be possible with considerable effort and expense. A restoration of the conventional electrotechnical operation of the module should be prevented as far as possible permanently by the irreversible separation and should only be possible with considerable technical effort and at great financial expense. For example this can be achieved in that separation of the separable part causes circuit-board conductors—possibly on several layers and/or inside a board—to be mechanically cut so that they cannot be easily connected back together again. Alternatively and/or additionally the module at least in the area of the specified separation edge can consist of a porous material which on separation disintegrates into several individual parts. Also, the separation surface can contain a layer which corrodes on contact with air and which as a result of contact with air after separation destroys circuit-board conductors or components.

According to a further embodiment, a drilled, milled, stamped, sawn and/or pierced recess and/or perforation as well as an irreversibly separable connection—for example in the form of a plug connection that can only be used once or in the form of an adhesive—can be provided along the specified separation edge. For example, the separable part and the remainder of the module can be glued together to create a conductive transition between the two parts so that the module can function in normal operation before separation of the separable part. If, however, the glued connection is loosened—for example by contact with water, heat or electricity—the two parts are separated from each other and neither of the parts can provide normal operation.

The conventional electrotechnical operation of the module corresponds to the normal or regular operation of a module integrated in a computer system. If the module in accordance with various embodiments is a graphics card in a workstation computer, normal operation for example would be the activation of a monitor and the presentation of a program interface or of a virtual desktop. If the module is installed in a telephone system, the conventional electrotechnical operation could for example be to activate telephone terminal equipment or to send call packets to a public communication network.

Essentially interacting circuit components of the module are understood in particular to mean that components of the separable part and components of the remainder of the module interact electronically and functionally in the active condition of the module before separation in order to provide the desired function of the module. In particular electronic information and/or messages are exchanged between these two parts and after separation neither of the two parts can perform the function of the unseparated module alone.

According to a further embodiment of the module, in particular several separable parts can also be provided which can be separated in each case from a remaining part of the module. Preferably, however, the module consists of two parts—the one separable part and the one remainder of the module.

According to a further embodiment, the separable part is provided with an unambiguous and/or counterfeit-proof identification feature. With this identification feature—for example a barcode, lettering with a module number and/or serial number of the module, and/or a chip or memory with identification information that can be read out—it can be determined by viewing or evaluating merely the separable part what type of module it is—for example a certain graphics card from a certain manufacturer in a certain version—and which module of a production series it is (in order to unambiguously identify a single module product). This can be compared with a database so that it can be determined unambiguously which sold, individual unit of a production series was deactivated by separating a separable part.

Preferably the identification feature can be a piece of information unambiguously assigned to a specific module stored in a radio tag—in one particular configuration also called an RFID chip (RFID: Radio Frequency Identification)—so that the information can be a read out by means of electromagnetic near field communication in a manner that it is largely secure against manipulation and free of readout errors.

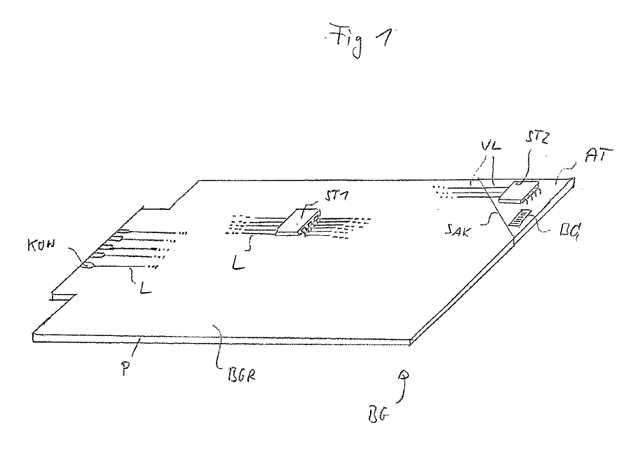

FIGS. 1 to 3 present an oblique schematic view of an electronic module BG which essentially includes a board P and two parts—a separable part AT and a remainder of the module BGR. In the present exemplary embodiment the board P is configured, as in known PCB arrangements, largely as a flat cuboid with two large cuboid surfaces for the assembly of components and several narrow cuboid sides. For contacting the board P with a further board—for example a backplane—or a housing, a projection is provided on board P. It can be assumed that the module BG is fitted with circuit components ST1 and ST2, whereby the circuit components ST1 are located on the remainder of the module and the circuit components ST2 are arranged on the separable part AT. In FIGS. 1-4 the circuit components ST1 and ST2 are merely indicated by a single chip and a connection of the respective components by circuit-board conductors L is visualized with dotted ends.

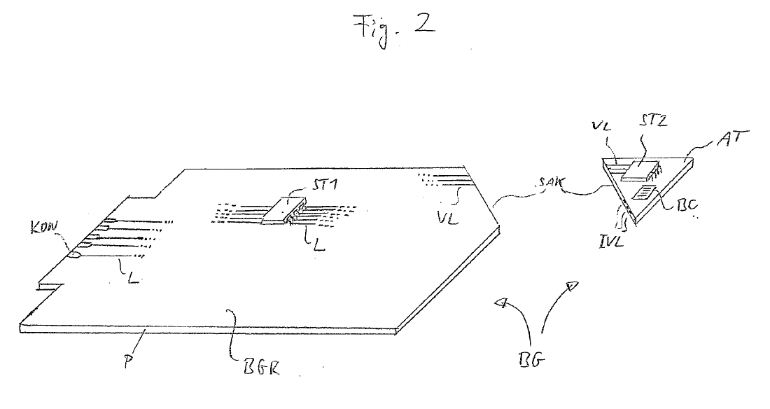

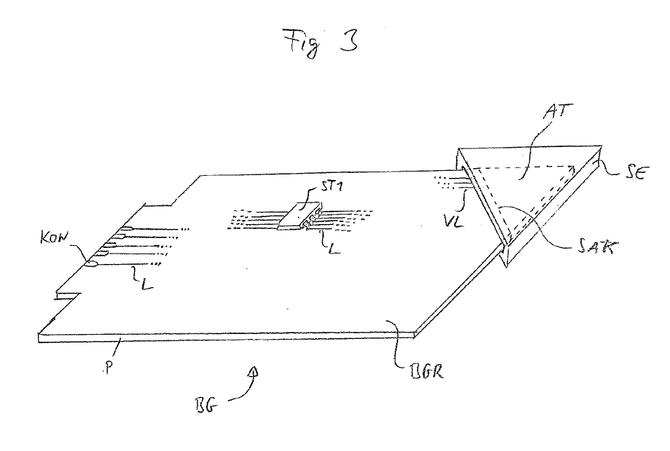

In FIG. 1 the separable part AT is firmly connected to the remainder of the module BGR along the specified separation edge SAK. The same applies to FIG. 3, whereby the module BG in FIG. 3 additionally exhibits a protective corner ST placed on the separable part AT as a stabilization mechanism. By contrast, FIG. 2 shows the condition of the module BG on which the separable part AT has been separated along the specified separation edge SAK from the remainder of the module BGR.

In FIGS. 1 to 4, 5a, 5b, 6 the specified separation edge SAK is a straight connecting line from a narrow side of the board P to a further narrow side of the board P. It is arranged in such a way that the separable part AT represents a wedge-shaped corner of the module BG which preferably is a multiple smaller than the module BG. Depending on the breaking strength of the board P this shape can be advantageous, but the specified separation edge SAK can also be any desired, curved, continuous or discontinuous line. As a result, the separable part AT can assume any body shape.

The remainder of the module BGR has the shape of the module BG without the separable part AT, i.e. in this exemplary embodiment in accordance with FIGS. 1 to 4 a board P with a separated or flattened corner. In addition to the circuit components ST2 essential for providing a conventional operation of the module—for example one or several integrated circuits—which are located on the separable part AT, there is also a barcode sticker BC on the separable part AT with preferably a serial number and an unambiguous identification number of the module BG as an unambiguous identification feature, as well as a connection for an electronic contact between the separable part AT and the remainder of the module BGR and thus between the circuit components ST2 and ST1 by means of connecting circuit-board conductors VL. The connecting circuit-board conductors VL should be arranged in such a way that they cross the specified separation edge SAK—at any desired angle. They can, for example, be provided for a transmission of signals and for supplying an operating voltage for the circuit component ST2. Alternatively to the barcode sticker BC a text referring to a module and/or a serial number could for example be etched into or affixed onto the board P or a component in the area of the separable part AT in order to identify the module.

The module BG shown in the FIGS. 1 to 4 is for example represented as a plug-in card for a computer system. For contacting the module BG to the computer bus system contacts KON with circuit-board conductors L are indicated. Such a module BG is for example a graphics card or a modem card (modem: modulator/demodulator) in a workstation computer or an interface or processor card for a modular communication system. Such a communication system is for example a flexibly configurable private branch exchange switching system with freely combinable equipment for exchange and extension lines.

In this exemplary embodiment it can be assumed that the module BG is provided for the activation of analog telephones in a private branch exchange switching system. Here the circuit components ST1 and ST2 are interlaced with each other in such a way that both circuit components ST1 and ST2 are essential for the conventional electrotechnical operation of module BG—i.e. for activation of the analog telephones—and interact to provide this functionality.

The original delivery condition of module BG as shown in FIG. 1 and provided by a manufacturer of the module BG is such that the separable part AT is firmly connected with the remainder of the module BGR. In an installed condition, the module BG thus provides the conventional function of activating the analog telephones (not shown) by means of the circuit components ST1 and ST2 which interact with each other in operation and send each other signals. If it becomes necessary to permanently deactivate the module BG at a later time and thus make it unable to function, the module BG can be separated into two parts along the specified separation edge SAK—in particular in dismantled and inactive condition. These two parts are the separable part AT and the remainder of the module BGR. The arrangement of the module BG after such separation is shown here in FIG. 2.

The separation step for the module BG not shown further in the figures represents part of the procedure in accordance with various embodiments and/or a use of the module SG for the permanent or at least partial deactivation of the module (BG) and is performed in particular by exerting mechanical influence on the separable part AT, so that the separable part AT is broken off from the remainder of the component BGR. To make the separation, an arrangement not described or shown in more detail can be used which carries out or supports the separation of the separable part AT mechanically or electromechanically. The breakage in particular causes the connecting lines VL and internal connecting lines IVL—in a multi-layer arrangement of connecting lines—between the circuit component ST2 and the circuit component ST1 to be cut—see FIG. 2. The separable part AT is thus disconnected and removed from the remainder of the module BGR.

Here it can be assumed that afterwards neither the circuit component ST1 nor the circuit component ST2 can provide the complete functionality for activation of the analog telephones. An insertion of the remainder of the module BG in the private branch exchange switching system should in no way activate the original function or the original, conventional electrotechnical operation of the module BG or of the remainder of the module BGR. This means that by separating the separable part AT along the specified separation edge SAK the module BG is permanently deactivated

The deactivated module BG can be identified here on the basis of the separable part AT, and in particular by means of the barcode sticker BC affixed to it. Insofar as the separable part AT is considerably smaller than the remainder of the module BGR this can be in particular advantageous in that by means of identification using the barcode sticker BC a separable part AT separated from the module BG can be used as evidence that the module BG has been deactivated.

The separation of the separable part AT should be carried out in particular in such a way that reconnection of the separable part AT with the remainder of the module BGR in order to reactivate the module BG is not possible by simple means. This is accomplished in the exemplary embodiment by separating the connecting circuit-board conductors VL and also the inner connecting circuit-board conductors IVL which run inside the board P preferably in several layers. An undesired recontacting of the cut connecting circuit-board conductors VL and IVL is only possible with a great deal of effort and expense and can therefore be regarded as a permanent separation of the two parts. It should not be possible to simply plug or solder the separable part AT and the remainder of the module BGR back together again. In particular, therefore, it should not be possible to restore the conventional operation.

In addition, in the present exemplary embodiment an irreversible separation of the separable part AT should have the consequence that an attempt to use the remainder of the module BGR for the originally intended purpose leads to a defined behavior that is different from operation—in particular the reporting of a fault, for example signaled by alarms or the use of LEDs on the remainder of the module BGR—and that further modules in a total system—in this case the private branch exchange telephone system—are not blocked or negatively influenced.

In order, however, to prevent an unintended, irreversible separation of the separable part AT from the remainder of the module BGR, a protective corner SE can as a stabilization mechanism be placed on the separable part AT and parts of the remainder of the module BGR as shown in FIG. 3, so that when the module BG is installed in the communication system an unintended breaking off of the separable part AT can be avoided or prevented. Providing protection by means of a protective corner SE is merely one of many possible configurations. Depending on the design of the module BG, various configurations prove to be advantageous by providing stabilization of the module BG in the area of the specified separation edge SAK. Alternatively to a protective corner SE placed on the separable part AT a guided slide can also be used on the board P as edge protection which can be pushed along a guide into a protective position in which unintended breaking off is prevented. The protective corner SE or further protective elements are in particular configured in non-conductive form—for example as plastic bodies—so that they do not affect the electrotechnical intended operation of the module. The protective corner SE or a similar mechanism can advantageously also be used in such a way that by means of the protective corner SE in a position outside a protective position, a breaking off or separation of the separable part is supported or facilitated, for example as a result of a better lever effect.

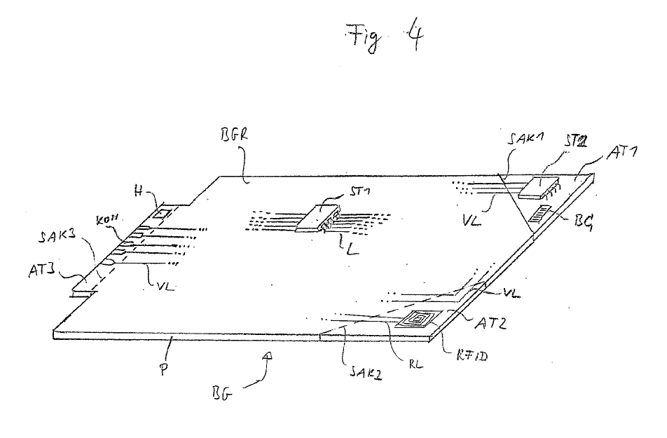

FIG. 4 is based on the arrangement of FIG. 1, whereby the specified separation edge known from FIG. 1 is now designated as SAK1 and the separable part known from FIG. 1 is designated as AT1. Also, two additional separable parts AT2 and AT3 are provided on the module BG, whereby AT2 similarly to AT1 represents a corner of the module BG and the separable part AT3 represents a cuboid of the module BG comprising the contacts KON. The connecting surface between the separable part AT2 and the remainder of the module BGR is the specified separation edge SAK2 and the connecting surface between the separable part AT3 and the remainder of the module BGR is the specified separation edge SAK3. In this exemplary embodiment the separable part AT3 exhibits a hologram H as a counterfeit-proof identification feature, while the separable part A2 exhibits an RFID chip RFID as a radio tag which is connected by circuit-board conductors RL with the circuit component ST1 of the remainder of the module BGR and from which a counterfeit-proof identification feature can be read. The remainder of the module BGR is defined here as the part which remains after separation of the three separable parts AT1, AT2 and AT3 from the module BG.

It can be assumed that the module BG in FIG. 4, continuing the example of the private branch exchange telephone system, represents a combination module to provide functions for coupling analog and digital telephones. This functionality is provided by the module BG insofar as all three separable parts AT1, AT2 and AT3 are connected with the remainder of the module BGR. On separation of the separable part AT1 it can be assumed that as a result the function of activating analog telephones is deactivated. The activation of digital telephones should, however, not be affected by separation of the separable part AT1. In the same way, a separation of the separable part AT2 should deactivate the activation of digital telephones. If the separable part AT1 is attached to the module, however, the module BG continues to provide the function of activating analog telephones. If both the separable parts AT1 and AT2 are separated it can be assumed that no activation whatsoever of analog and digital telephones would be possible but that the module BG or the remainder of the module BGR including the separable part AT3 still attached to it can continue to provide additional functions for the private branch exchange telephone system. These include in particular switching tasks or a direct activation of further terminal units, such as data terminals.

Such a setup with two or several separable parts AT1, AT2 in particular has the advantage that a manufacturer only needs to produce one module BG for the performance of various functions, whereby the module pieces of the production series can be simply configured by separation of separable parts AT1 and/or AT2. This provides a great deal of flexibility but is also highly secure against manipulation as the separable parts AT1 and/or AT2 can already be separated by the manufacturer or a service operation. As a result, the manufacturer can restrict production to a common production series of modules and by separation of separable parts can provide modules for different functions because by separation of separable parts only parts having the functionality of the module are deactivated, which means that higher efficiency can be achieved in the manufacturing process.

In addition, the module BG in FIG. 4 still exhibits the separable part AT3 which similarly to the explanation in accordance with FIG. 1 and FIG. 2 is provided for the permanent deactivation of the module BG. If therefore the separable part AT3 is separated from the rest of the module BG along a specified separation edge SAK3 the module BG is irreversibly deactivated, regardless of whether the separable parts AT1 and AT2 are still connected to the module BG.

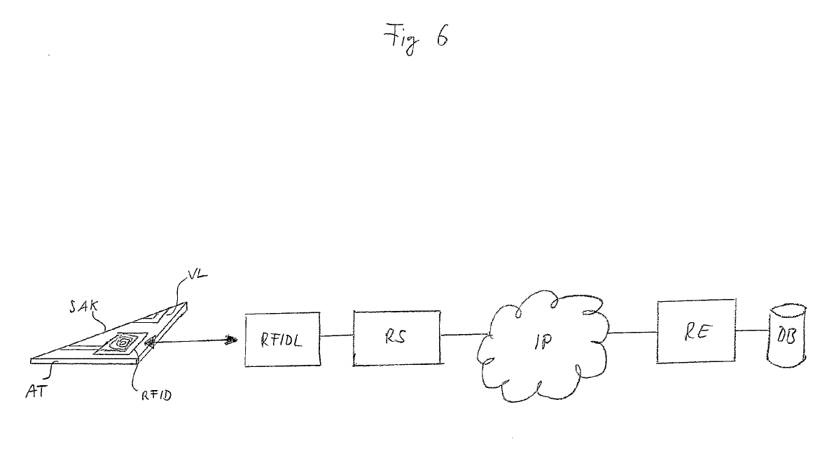

The mentioned RFID chip RFID on the separable part AT2 can in particular be a radio tag transponder which can be read by an RFID reader—for example RFIDL in FIG. 6—whereby the RFID chip RFID in particular can communicate unambiguous identification information of the module BG to the RFID reader RFIDL. Therefore again similarly to the barcode sticker BC from FIG. 1 an identification of the module BG and/or the separable part AT2 is possible within the production series.

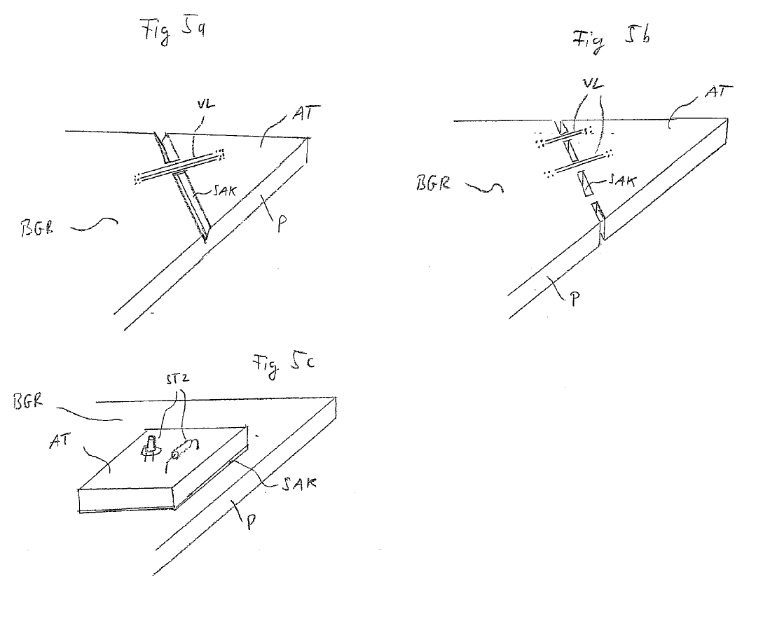

A different configuration of the specified separation edges SAK1, SAK2, SAK3 already indicated in FIG. 4 is explained in more detail in the following in FIG. 5. Here it should be pointed out that in FIG. 4 the specified separation edge SAK1 is represented as a continuous line whereas the specified separation edges SAK2 and SAK3 are represented as a dotted line, whereby the dotted representation of the last-mentioned line is intended to indicate that for example a broken line of drill holes can represent a specified separation edge SAK2 or SAK3.

Three such configurations are represented by way of example and not exhaustively in FIG. 5, whereby in all illustrations re FIG. 5 merely one section of the module BG comprising the separable part AT is to be seen in an oblique perspective representation. In FIG. 5a recess is etched in the board P along the specified separation edge SAK, which recess facilitates a separation of the separable part AT, whereby an incorrect separation not along the specified separation edge SAK is at least not supported. Circuit-board conductors VL on the surface or inside the board P should not be affected by the etching. Alternatively, openings can be provided along the specified separation edge SAK, whereby the circuit-board conductors VL run across bridges to the separable part AT. Such an embodiment is illustrated in FIG. 5b.

A third alternative embodiment is shown in FIG. 5c in which a module BG consisting of a board P has a further module glued onto it on one of the large surfaces of the board, whereby the further module represents the separable part AT. In this case too, the separable part AT contains essential circuit elements ST2 for the intended operation—indicated in FIG. 5c by two passive components with in each case two contacts to the separable part AT. The circuit component ST2 of the separable part AT is activated for example by contacts between the board P and the separable part AT or by means of induction. The separable part AT can in this case be separated for example by mechanical force or by the effect of heat, whereby the heat causes the adhesive to loosen and the separable part AT can be removed from the remainder of the module BGR. It should not be easily possible to glue the separated contacts back together again or to reconnect them.

In addition to the three configurations presented in FIG. 5 numerous other contacting possibilities between the separable part AT and the remainder of the module BGR are conceivable and depending on the configuration of the module BG are advantageous.

FIG. 6 shows an arrangement and illustrates a procedure in which a separated separable part AT can be registered on an evaluation computer RE. In FIG. 6 a separable part AT is shown with an RFID transponder chip RFID contained on it which by means of an RFID reader RFIDL communicates an unambiguous serial number and/or identification information of the module BG. When this information is read by the RFID reader RFIDL it can be passed on to a communication computer RS which can connect with the evaluation computer via a packet-oriented network IP—for example the worldwide internet. The communication computer RS can communicate the information—preferably by means of browser-based methods such as web services—to the evaluation computer RA which in turn can write this information in an evaluation database DB and make a comparison with further manufacturer- or customer-related data.

If for example the communication computer RS is located on the company premises of a customer of the module BG and the evaluation computer RE is located on the premises of a manufacturer of the module BG it is easy for the customer to prove to the manufacturer that a module BG on its premises has been deactivated without a module BG or a part of a module BG—for example represented by the separable part AT—having to be sent to the manufacturer. After receipt of the confirmation that the module BG has been deactivated through communication of the above-mentioned information to the evaluation computer RE, the manufacturer can now for example send back via the packet-oriented network IP a release code to a computer of the customer in order to be able to activate a supplied alternative module at the customer. In this way it is possible to easily perform a migration of older modules to newer modules without the customer being able to exploit the migration to its advantage and without the manufacturer having to expensively send service personnel to the customer.

Alternatively to the evaluation illustrated in FIG. 6 via the packet-oriented network IP the separable part AT can also be sent to an evaluation unit for verification that the module BG has been scrapped.

The arrangements and procedures presented in the figures are advantageous insofar as a deactivation of modules can be easily ensured by them and a reactivation of the module is not possible and it is not necessary to destroy the module or to collect scrapped modules, both of which involve effort and expense. Moreover, it is advantageous that by using several separable parts various functions of a module can be permanently deactivated. This can for example include deactivating a test function which is intended to be performed only on the manufacturer's premises and which is not intended to be present in a system delivered to a customer. In such a configuration the separation of the separable part should merely deactivate the test functionality and not negatively influence an intended use—as an alternative function to the test function—in a computer system.

Stated in general terms and illustrated once again, the intended electrotechnical operation of the module in accordance with various embodiments can therefore also be a test operation of the module—activated by a testing unit. In addition to this test operation the module can be used in normal or regular operation, whereby depending on the configuration of the module the separation of the separable part does not need to have any influence on normal operation. Preferably, the separation can deactivate the test operation and effect lasting fault-free starting in normal operation.

If an RFID chip is used on the separable part—as represented in some of the previous figures—it can be ensured with suitable wiring of the RFID chip that the latter can only be read out if the separable part has been separated together with the RFID chip. A readout of the RFID chip on the unseparated module can in particular be prevented by wiring the RFID chip through a remainder of the module in such a way that in the installed and unseparated condition of the module a readout of the RFID chip in the unseparated and thus wired condition is prevented. Only through separation of the separable part AT together with the RFID chip should it be possible to read out the chip using a reader. This can for example be accomplished in that the connecting lines (RL in FIG. 4) to the RFID chip are short-circuited in the unseparated condition by a direct connection on the remainder of the module BGR and therefore deactivate the RFID chip.

A deactivation of a module ensured in accordance with various embodiments can in particular be advantageous for systems on which a new software status is imported into the system by way of a migration or upgrade, whereby dependencies on the software status of the modules exist and an exchange of the software status can and must only occur in harmony with an exchange of modules. This is frequently the case in known communication systems, whereby usually a manual or instructions explain which modules have to be removed from the system and/or replaced by new modules before the new software status is imported. A further operation of a module with a new software status can in particular lead to faulty functioning which should be prevented in a reliable manner. The procedure and the module in accordance with various embodiments can be used for this purpose.

To make installation difficult or impossible after separation of the separable part owing to given mechanical conditions, the separable part can exhibit a means of fastening in order to attach the original, unseparated module to a housing, so that after separation of the separable part from the module the installation of the remainder of the module in the housing is prevented.

What is claimed is:

1. An electronic module, comprising
a specified separation edge for the mechanical, irreversible separation of a separable part of the module from a remainder of the module, wherein both the separable part and also the remainder of the module have essentially interacting circuit components for a conventional electrotechnical operation of the module.

2. The electronic module according to claim 1,
wherein
through the separation of the separable part, the electrotechnical operation of the module is permanently deactivated or at least partially restricted.

3. The electronic module according to claim 1, wherein
after separation of the separable part, the electrotechnical operation is performed neither by the separated separable part nor the remainder of the module.

4. The electronic module according to claim 1, wherein
along the specified separation edge at least one of a recess, a perforation, and a separable connection are provided.

5. The electronic module according to claim 1, wherein
the specified separation edge connects a narrow side of the module with a further narrow side of the module continuously along a wide side of the module.

6. The electronic module according to claim 1, wherein
the specified separation edge is on a board.

7. The electronic module according to claim 1, wherein
a circuit-board conductor for the electrotechnical operation crosses the specified separation edge and wherein separation of the separable part causes the crossing conductor to be cut.

8. The electronic module according to claim 7, wherein
the conductor is arranged on at least one of: a surface and inside a board.

9. The electronic module according to claim 1, wherein
the module exhibits a removable or interruptible stabilization mechanism, so that the separable part is fixed by the attached or applied stabilization mechanism.

10. The electronic module according to claim 1, wherein
the separable part exhibits at least one of: an unambiguous and counterfeit-proof identification feature.

11. The electronic module according to claim 10, wherein
the identification feature is stored in and can be read out from a radio tag or a memory on the separable part.

12. The electronic module according to claim 10, wherein
the identification feature is located on at least one of: a sticker on the separable part, is configured as fixedly connected or recessed lettering, and as a hologram on the separable part.

13. The electronic module according to claim 10, wherein
from the identification feature at least one of: a module identification number and a serial number for the module can be determined.

14. The electronic module according to claim 1, wherein
a radio tag located on the separable part is inactive in the unseparated condition through the circuit component located on the remainder of the module and on separation of the separable part this circuit component is separated from the radio tag and the radio tag is then activated.

15. A method for the permanent or at least partial deactivation of an electronic module, comprising the step of:
mechanically irreversibly separating a separable part of the module along a specified separation edge, wherein both the separable part and the remainder of the module incorporate essentially interacting circuit components for an intended electrotechnical operation of the module.

16. The method according to claim 15,
wherein
a radio reader is linked via a network to an evaluation computer and that an identification feature communicated to the radio reader by a radio tag is communicated further to the evaluation computer.

17. The method according to claim 15, wherein
the module, in addition to the conventional electrotechnical operation, performs a further conventional function and that after separation of the separable part the remainder of the module continues to perform the further intended function.

18. The method according to claim 15, wherein
after separation of the separable part the remainder of the module performs a different, alternative function to the intended electrotechnical operation.

19. The method according to claim 15, wherein
through the separation of the separable part, the electrotechnical operation of the module is permanently deactivated or at least partially restricted.

20. The method according to claim 15, wherein
after separation of the separable part, the electrotechnical operation is performed neither by the separated separable part nor the remainder of the module.
